(19) United States
(12) Patent Application Publication
(10) Pub. No.: US 2010/0317155 A1
(43) Pub. Date: Dec. 16, 2010

(54) MULTIFUNCTIONAL DIE ATTACHMENT FILM AND SEMICONDUCTOR PACKAGING USING THE SAME

(76) Inventors: Byoung-Un Kang, Seoul (KR); Joon-Mo Seo, Gyeonggi-do (KR); Choong-Hyun Sung, Seoul (KR); Jae-Hoon Kim, Seoul (KR); Soon-Young Hyun, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/526,313

(22) PCT Filed: Aug. 3, 2007
(86) PCT No.: PCT/KR07/03748

§ 371 Date: May 3, 2010

(30) Foreign Application Priority Data
Feb. 9, 2007 (KR) 10-2007-0013933
Feb. 9, 2007 (KR) 10-2007-0013935

(51) Int. Cl. H01L 21/50; B32B 7/02; B32B 7/12; C09J 7/00; B32B 5/02; B32B 27/00; B32B 27/18

(52) U.S. Cl. 438/113; 438/118; 428/343; 428/355 EP; 428/355 AC; 428/355 BL; 428/355 N; 428/355 R; 428/212; 428/214; 428/323; 257/E21.499

(57) ABSTRACT

A multifunctional die attachment film used in a semiconductor packaging process includes a first die attachment film attached to a surface of a wafer having fine circuit patterns and solder bump patterns and having a first adhesive strength; and a second die attachment film attached on the first die attachment film and having a second adhesive strength with a wafer, a die chip, PCB and a flexible board, and the multifunctional die attachment film serves as a backgrinding tape in a backgrinding process, and after the backgrinding process is completed, the multifunctional die attachment film is not removed, but is used to attach a die chip to a connection member. And, the present invention utilizes the die attachment film as a backgrinding tape in the backgrinding process and concurrently a wafer protection means in a wafer dicing process, thereby preventing sawing burr, scratches or cracks.

### TECHNICAL FIELD

The present invention relates to a multifunctional die attachment film, and in particular, to a multifunctional die attachment film used in a semiconductor packaging process, which serves as a backgrinding tape in a backgrinding process and after the backgrinding process, is not removed but used to attach a die chip to a connection member, and a semiconductor packaging method using the same.

### BACKGROUND ART

Generally, a process for fabricating a semiconductor chip involves a process for forming fine circuit patterns in a semiconductor wafer having a predetermined thickness, a process for backgrinding a back surface of the wafer and a process for cutting the wafer into individual die chips in conformity with a predetermined device standard and packaging the individual die chips into semiconductor devices.

In the backgrinding process of the semiconductor chip fabricating process, a backgrinding tape is attached to a front surface of the wafer having the fine circuit patterns, the backgrinding tape attached surface is absorbed by a grind chuck, the back surface of the wafer is closely placed on a sawing die, and the wafer is background while a slurry is injected such that the wafer is 150 to 200□ thick. In the backgrinding process, large pressure or mechanical shock is applied to the wafer, and the backgrinding tape prevents damage of the wafer which may occur during this process.

Conventionally, however, it requires to remove the backgrinding tape from the front surface of the wafer after the backgrinding process. And, a dicing film is attached to the back surface of the wafer after the backgrinding process, the wafer is placed on the sawing die using the dicing film, and then the backgrinding tape is removed, at this time, in the case that an adhesive strength of the dicing tape attached on the surface opposite to the backgrinding tape attached surface of the wafer is weaker than that of the backgrinding tape, the wafer may warp.

Meanwhile, during a dicing process, faults such as sawing bun, scratches or cracks may occur to the surface of the wafer having the fine circuit patterns, however the dicing process is performed without any protection means in the prior art. And, after the dicing process, as each die chip is picked up using a pickup pin and mounted on an object for packaging (for example, a lead frame), warpage may occur to the thin die chip in the direction of pickup, and in the case of excessive warpage, an unexpected fault may occur to the die chip, thereby reducing reliability of a resultant semiconductor device.

### DISCLOSURE OF INVENTION

### Technical Problem

The present invention is designed to solve the problems of the prior art, and therefore it is an object of the present invention to provide a multifunctional die attachment film used in a semiconductor packaging process, which may serve as a die attachment film used to attach a die chip to a connection member and concurrently a backgrinding tape in a backgrinding process before the die attaching process, and a semiconductor device packaging method using the same.

### Technical Solution

In order to achieve the above-mentioned objects, a multifunctional die attachment film used in a semiconductor packaging process includes a first die attachment film attached to a surface of a wafer having fine circuit patterns and solder bump patterns and having a first adhesive strength; and a second die attachment film attached on the first die attachment film and having a second adhesive strength, and the multifunctional die attachment film serves as a backgrinding tape in a backgrinding process of a semiconductor packaging process, and after the backgrinding process is completed, is not removed but used to attach a die chip to a connection member.

Preferably, each of the first die attachment film and the second die attachment film is made of transparent or translucent materials.

In the present invention, the multifunctional die attachment film has a laminated stack structure of the first die attachment film and the second die attachment film, and each of the first die attachment film and the second die attachment film is made of any one resin material selected from the group consisting of an epoxy-based resin, an acryl-based resin, a silicon-based resin, a rubber-based resin, an urethan-based resin and an elastomer-based resin.

Preferably, the first adhesive strength is 10 to 2,000 gf/□ at 25° C. based on silicon wafer surface attachment, and the second adhesive strength is 10 to 2,000 gf/□ at 25° C. based on AUS308 surface attachment.

Preferably, each of the first die attachment film and the second die attachment film has a moisture absorption rate of 0 to 2% wt based on a moisture resistance test (JL2) of 85° C./60% moisture for seven days.

Preferably, each of the first die attachment film and the second die attachment film has a storage modulus of 10⁴ to 10¹⁰ Pa at 50° C., and more preferably, the second die attachment film has a storage modulus of 10⁶ to 10⁹ Pa at 50° C.

Preferably, at least one of the first die attachment film and the second die attachment film contains conductive fillers, and the conductive fillers is contained with 0.5 to 70 volume % to volume of the resin material.

Further, a ratio of thickness of a film with the conductive fillers to thickness of a film without the conductive fillers is 10:1 to 0.1:1, more preferably, 4:1 to 0.5:1.

In the present invention, the conductive fillers are made of any one conductive metal selected from the group consisting of gold, silver, copper and nickel, or a core-shell configured organic material coated with the conductive metal.

In the present invention, the conductive fillers have a particle diameter of 0.05 to 50 □.

Preferably, an intermediate layer is interposed between the first die attachment film and the second die attachment film to form a multilayered structure, and is made of any one or at least two selected from the group consisting of polyester, polyethylene, polyethyleneterephthalate, vinyl, polypropylene, polystyrene, polycarbonate, polyvinylchloride, polymethylmethacrylate, polyacetal, polyoxymethylene, poly-butyleneterephthalate, acrylonitrile-butadiene-styrene and ethylene-vinylalcohol copolymer.

In order to achieve the above-mentioned objects, a semiconductor packaging method using the multifunctional die attachment film according to an aspect of the present invention includes (a) attaching the die attachment film to a surface of a wafer having fine circuit patterns and solder bump patterns such that a first die attachment film surface of the die attachment film faces the wafer; (b) backgrinding a back surface of the wafer and then attaching a dicing film thereto; (c) sawing the wafer having the die attachment film into at least one die chip; and (d) removing the dicing film from the die chip and then electrically connecting the die chip to a connection member by flip chip bonding using solder bumps such that a second die attachment film surface of the die attachment film faces the connection member.

In order to achieve the above-mentioned objects, a semiconductor packaging method using the multifunctional die attachment film according to another aspect of the present invention includes (a) attaching the die attachment film to a surface of the wafer having fine circuit patterns and solder bump patterns such that a first die attachment film surface of the die attachment film faces the wafer; (b) backgrinding a back surface of the wafer and then attaching a dicing die attachment film thereto; (c) sawing the wafer having the die attachment film into at least one die chip; and (d) removing a dicing film layer of the dicing die attachment film from the die chip, attaching the die chip to a connection member, and then electrically connecting another die chip to the die chip by flip chip bonding using solder bumps such that the another die chip faces the die attachment film surface.

In the present invention, the connection member is any one selected from the group consisting of PCB (Printed Circuit Board), a lead frame and a die chip.

### BRIEF DESCRIPTION OF THE DRAWINGS

FIG. 1 is a cross-sectional view illustrating a die attachment film according to a preferred embodiment of the present invention.

FIG. 2 is a flow chart illustrating a semiconductor packaging method according to a preferred embodiment of the present invention.

FIGS. 3 to 6 are cross-sectional views illustrating a semiconductor packaging process according to a preferred embodiment of the present invention.

### BEST MODE FOR CARRYING OUT THE INVENTION

Hereinafter, preferred embodiments of the present invention will be described in detail with reference to the accompanying drawings.

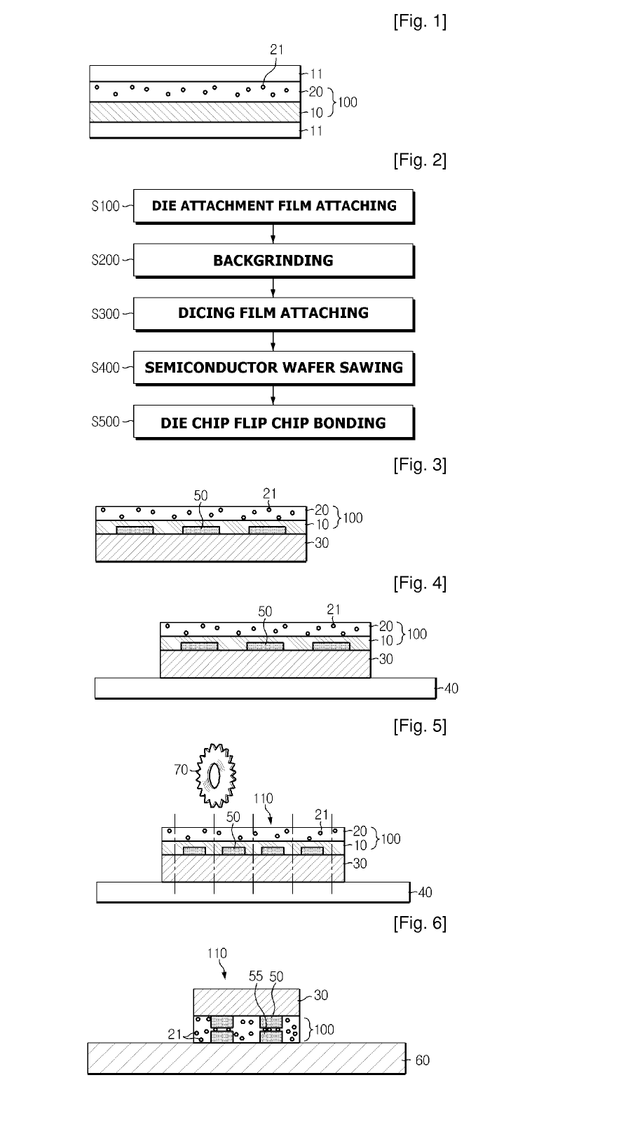

FIG. 1 is a cross-sectional view illustrating a die attachment film according to a preferred embodiment of the present invention.

Referring to FIG. 1, the die attachment film 100 includes a first die attachment film 10 attached to a surface of a wafer having fine circuit patterns and solder bump patterns 50, a second die attachment film 20 attached on the first die attachment film 10, and a protection film 11 attached on both surfaces of the die attachment film 100 for protecting the die attachment film 100.

As shown in FIG. 1, the protection film 11 protects adhesive surfaces of the die attachment film 100 from impurities, and may use polyethylene or polyethyleneterephthalate (PET). However, the present invention is not limited in this regard.

The die attachment film 100 has a laminated stack structure of the first die attachment film 10 and the second die attachment film 20.

Here, the first die attachment film 10 is attached to the surface of the wafer having the fine circuit patterns and the solder bump patterns 50 with a first adhesive strength, and is a material layer required for high adhesive strength with a die chip separated from the wafer. And, the second die attachment film 20 is attached on the first die attachment film 10 with a second adhesive strength, and is a material layer absorbed by a grind chuck for fixing the wafer in a backgrinding process. In consideration of this point, the first adhesive strength is 10 to 2,000 gf/□ at 25° C. based on silicon wafer surface attachment, and the second adhesive strength is 10 to 2,000 gf/□ at 25° C. based on AUS308 surface attachment.

And, in a wafer dicing process of a semiconductor packaging process, high heat is generated from the wafer 30, and a coolant is used to cool the wafer 30. Therefore, the die attachment film 100 should have a moisture resistant property, and thus requires a low moisture absorption rate. In consideration of this point, the die attachment film 100 has a moisture absorption rate of 0 to 2% wt based on a moisture resistance test (JL2) of 85° C./60% moisture for seven days.

Meanwhile, in a semiconductor pickup process of the semiconductor packaging process, when the die chip is picked up by a pickup pin, warpage may occur to the thin die chip in the direction of pickup, moreover, when the die chip is attached to a lead frame, warpage may occur to the die chip due to a suction tool of a chip mount head. To prevent these problems, the die attachment film 100 has a storage modulus of 10⁴ to 10¹⁰ Pa at 50° C., and more preferably, the second die attachment film 100 has a storage modulus of 10⁶ to 10⁹ Pa at 50° C.

And, the die attachment film 100 is capable of serving as a backgrinding tape in the backgrinding process, and after the backgrinding process is completed, the die attachment film 100 is not removed, but remains as it is during the subsequent wafer dicing process. Therefore, the die attachment film 100 is made of transparent or translucent materials to show the surface of the wafer having the fine circuit patterns in the wafer dicing process.

Each of the first die attachment film 10 and the second die attachment film 20 may use an epoxy-based resin, an acryl-based resin, a silicon-based resin, a rubber-based resin, an urethan-based resin or an elastomer-based resin. However, the present invention is not limited in this regard.

And, an intermediate layer may be interposed between the first die attachment film 10 and the second die attachment film 20 to form the die attachment film 100 of a multilayered structure, and the intermediate layer is made of polyester, polyethylene, polyethyleneterephthalate, vinyl, polypropylene, polystyrene, polycarbonate, polyvinylchloride, polymethylmethacrylate, polyacetal, polyoxymethylene, poly-butyleneterephthalate, acrylonitrile-butadiene-styrene or ethylene-vinylalcohol copolymer. However, the present invention is not limited in this regard.

And, at least one of the first die attachment film 10 and the second die attachment film 20 of the die attachment film 100 contains conductive fillers 21 for good electrical bondability between the die chip and the connection member when the die chip is flip chip bonded to the connection member. For example, the conductive fillers 21 are made of any one selected from a conductive metal such as gold, silver, copper or nickel, and a core-shell configured organic material coated with the conductive metal. However, the present invention is not limited in this regard. And, the conductive fillers 21 are contained with 0.5 to 70 volume % to volume of the resin material of the second attachment film 20, and a particle diameter of the conductive fillers 21 is 0.05 to 50 □.

FIG. 2 is a flow chart illustrating a semiconductor packaging method according to a preferred embodiment of the present invention, and FIGS. 3 to 6 are cross-sectional views illustrating a semiconductor packaging process according to a preferred embodiment of the present invention.

Referring to FIGS. 2 to 6, in the semiconductor packaging method according to a preferred embodiment of the present invention, as shown in FIG. 3, the protection film 11 is removed from the die attachment film 100, and the die attachment film 100 is attached to the surface of the wafer 30 having the fine circuit patterns and solder bump patterns 50 such that the first die attachment film 10 surface of the die attachment film 100 faces the wafer 30 (S100).

Subsequently, the wafer 30 is fixed such that the second die attachment film 20 surface formed on the first die attachment film 10 attached to the wafer 30 is absorbed by a grind chuck, and backgrinding is performed (S200).

Next, as shown in FIG. 4, a dicing film 40 is attached to the background back surface of the wafer 30 having the die attachment film 100 attached thereto (S300).

Then, as shown in FIG. 5, the wafer 30 is fixed such that the dicing film 40 attached to the back surface of the wafer 30 is attached to a dicing table, and the wafer 30 is sawn into individual die chips 110 by a dicing saw 70 (S400).

Next, the die chip 110 is picked up, and the dicing film 40 is removed from the die chip 110. And, as shown in FIG. 6, the die chip 110 is turned over such that the second attachment film 20 containing the conductive fillers 21 faces a connection member 60, and flip chip bonding is performed to establish an electrical connection between the die chip 110 and the connection member 60 using solder bumps 50 (S500). At this time, the conductive fillers 21 support the electrical connection between the die chip 110 and the connection member 60 more closely.

Here, the connection member 60 is any one selected from PCB (Printed Circuit Board), a lead frame and a die chip, and is electrically connectable to the die chip 110. However, the present invention is not limited to a specific type of the connection member 60.

As described above, the die attachment film 100 according to the present invention performs a basic function for attaching the die chip 110 to the connection member 60, and serves as a backgrinding tape during the backgrinding process and concurrently an underfill between the die chip 110 and the connection member 60 during the flip chip bonding process.

Meanwhile, alternatively the dicing film 40 attached to the back surface of the wafer 30 may be replaced by a dicing die attachment film (not shown) in step s300, and in this case, the dicing die attachment film (not shown) surface of the die chip 110 may be attached to the connection member 60 and another die chip (not shown) may be attached to the die attachment film 100 surface of the die chip 110, and thus two different die chips may be electrically connected to each other.

As such, it should be understood that the detailed description and specific examples, while indicating preferred embodiments of the invention, are given by way of illustration only, since various changes and modifications within the spirit and scope of the invention will become apparent to those skilled in the art from this detailed description.

### INDUSTRIAL APPLICABILITY

The semiconductor packaging method according to the present invention may utilize the die attachment film for attaching the die chip to the connection member as a backgrinding tape in the backgrinding process and concurrently a wafer protection means in the wafer dicing process, thereby preventing sawing bun, scratches or cracks which may occur to the surface of the wafer. And, the present invention may eliminate a need for removing the backgrinding tape after the backgrinding process. Further, the present invention may form the die attachment film from a backgrinding tape material and an underfill material, thereby reducing semiconductor packaging costs.

1. A multifunctional die attachment film used in a semiconductor packaging process, the multifunctional die attachment film comprising:
a first die attachment film attached to a surface of a wafer having fine circuit patterns and having a first adhesive strength; and
a second die attachment film attached on the first die attachment film and having a second adhesive strength lower than the first adhesive strength,
wherein at least one of the first die attachment film and the second die attachment film contains conductive fillers, and
wherein the multifunctional die attachment film serves as a backgrinding tape in a backgrinding process of a semiconductor packaging process, and after the backgrinding process is completed, the multifunctional die attachment film is not removed but used to attach a die chip to a connection member.

2. The multifunctional die attachment film according to claim 1,
wherein each of the first die attachment film and the second die attachment film is made of transparent or translucent materials.

3. The multifunctional die attachment film according to claim 2,
wherein the first adhesive strength is 10 to 2,000 gf/cm at 25° C. based on silicon wafer surface attachment, and the second adhesive strength is 10 to 2,000 gf/cm at 25° C. based on AUS308 surface attachment.

4. The multifunctional die attachment film according to claim 2 or 3,
wherein each of the first die attachment film and the second die attachment film has a moisture absorption rate of 0 to 2% wt based on a moisture resistance test (JL2) of 85° C./60% moisture for seven days.

5. The multifunctional die attachment film according to claim 4,
wherein each of the first die attachment film and the second die attachment film has a storage modulus of 10⁴ to 10¹⁰ Pa at 50° C.

6. The multifunctional die attachment film according to claim 5,
wherein the second die attachment film has a storage modulus of 10⁶ to 10⁹ Pa at 50° C.

7. The multifunctional die attachment film according to claim 6,
wherein each of the first die attachment film and the second die attachment film is made of any one resin material selected from the group consisting of an epoxy-based resin, an acryl-based resin, a silicon-based resin, a rubber-based resin, an urethan-based resin and an elastomer-based resin.

8. (canceled)

9. The multifunctional die attachment film according to claim 7,
wherein the conductive fillers are contained in the die attachment film with 0.5 to 70 volume % to volume of the resin material.

10. The multifunctional die attachment film according to claim 9,
wherein the conductive fillers are contained only in the second die attachment film, and a thickness ratio of the second die attachment film to the first die attachment film is 10:1 to 0.1:1.

11. The multifunctional die attachment film according to claim 10,
wherein a particle diameter of the conductive fillers is 0.05 to 50 μm.

12. The semiconductor packaging method according to claim 11,
wherein the conductive fillers are made of any one of a conductive metal selected from the group consisting of gold, silver, copper and nickel, and a core-shell organic material coated with the conductive metal.

13. (canceled)

14. A semiconductor packaging method using the die attachment film according to any one of claims 1 to 12, the semiconductor packaging method comprising:
(a) attaching the die attachment film to a surface of a wafer having fine circuit patterns such that a first die attachment film surface of the die attachment film faces the wafer;
(b) backgrinding a back surface of the wafer and then attaching a dicing film thereto;
(c) sawing the wafer having the die attachment film into at least one die chip; and
(d) removing the dicing film from the die chip and then electrically connecting the die chip to a connection member by flip chip bonding using solder bumps such that a second die attachment film surface of the die attachment film faces the connection member.

15. The semiconductor packaging method according to claim 14,
wherein the connection member is any one selected from the group consisting of PCB (Printed Circuit Board), a lead frame and a die chip.

16. (canceled)

17. (canceled)

18. A semiconductor packaging method using the die attachment film according to any one of claims 1 to 12, the semiconductor packaging method comprising:
(a) attaching the die attachment film to a surface of a wafer having fine circuit patterns such that a first die attachment film surface of the die attachment film faces the wafer;
(b) backgrinding a back surface of the wafer and then attaching a dicing die attachment film thereto;
(c) sawing the wafer having the die attachment film into at least one die chip; and
(d) removing a dicing film layer of the dicing die attachment film from the die chip, attaching the die chip to a connection member, and then electrically connecting the die chip to another die chip by flip chip bonding using solder bumps such that the another die chip faces the die attachment film surface of the die chip.

19. The semiconductor packaging method according to claim 18,
wherein the connection member is any one selected from the group consisting of PCB (Printed Circuit Board), a lead frame and a die chip.

20. (canceled)

21. (canceled)
